(19) United States
(12) Patent Application Publication
(10) Pub. No.: US 2014/0076392 A1
(43) Pub. Date: Mar. 20, 2014

(54) SOLAR CELL

(71) Applicants: Chih Ching LIN, Hsinchu City (TW); Yong-Ping CHAN, New Taipei City (TW); Wei-Chun HSU, Taipei City (TW); Chen-Yun WANG, Kaohsiung City (TW)

(72) Inventors: Chih Ching LIN, Hsinchu City (TW); Yong-Ping CHAN, New Taipei City (TW); Wei-Chun HSU, Taipei City (TW); Chen-Yun WANG, Kaohsiung City (TW)

(73) Assignee: TSMC SOLAR LTD., Taichung City (TW)

(21) Appl. No.: 13/621,879

(22) Filed: Sep. 18, 2012

(51) Int. Cl. H01L 31/0216; H01L 31/18

(52) U.S. Cl. 136/256; 438/98; 257/E31.126

(57) ABSTRACT

A thin film solar cell and process for forming the same. The solar cell includes a bottom electrode layer, semiconductor light absorbing layer, and a TCO top electrode layer. In one embodiment, a TCO seed layer is formed between the top electrode and absorber layers to improve adhesion of the top electrode layer to the absorber layer. In one embodiment, the seed layer is formed at a lower temperature than the TCO top electrode layer and has a different microstructure.

### FIELD

The present disclosure generally relates to photovoltaic solar cells, and more particularly to thin film solar cells and methods for forming same.

### BACKGROUND

Thin film photovoltaic (PV) solar cells are one class of energy source devices which harness a renewable source of energy in the form of light that is converted into useful electrical energy which may be used for numerous applications. Thin film solar cells are multi-layered semiconductor structures formed by depositing various thin layers and films of semiconductor and other materials on a substrate. These solar cells may be made into light-weight flexible sheets in some forms comprised of a plurality of individual electrically interconnected cells. The attributes of light weight and flexibility gives thin film solar cells broad potential applicability as an electric power source for use in portable electronics, aerospace, and residential and commercial buildings where they can be incorporated into various architectural features such as roof shingles, facades, and skylights.

Thin film solar cell semiconductor packages generally include a bottom contact or electrode formed on the substrate and a top contact or electrode formed above the bottom electrode. Top electrodes have been made for example of light transparent conductive oxide (“TCO”) materials. TCO materials are susceptible to attack and degradation by environment factors including water, oxygen, and carbon dioxide. Such TCO degradation may induce high series resistance (Rs) and result in lower solar energy conversions efficiencies for the solar cell.

An improved thin film solar cell is therefore desired that addresses the foregoing problems.

### BRIEF DESCRIPTION OF THE DRAWINGS

The features of the preferred embodiments will be described with reference to the following drawings where like elements are labeled similarly, and in which:

FIG. 1 is a cross-sectional side view of a first embodiment of a thin film solar cell according to the present disclosure;

FIG. 2 is a flow chart showing sequential steps in an exemplary process for the formation thereof;

FIG. 3 is a diagram of an apparatus for depositing TCO film layers on a substrate;

FIGS. 4 and 5 are scanning electron microscope images of a TCO seed layer and TCO bulk top electrode layer, respectively.

FIG. 6 is an X-ray diffraction curve comparing a TCO seed layer and TCO bulk top electrode layer formed according to the present disclosure;

FIG. 7 is a cross-sectional side view of a second embodiment of a thin film solar cell according to the present disclosure;

FIG. 8 is a flow chart showing sequential steps in an exemplary process for the formation thereof;

FIG. 9 is a cross-sectional side view of a third embodiment of a thin film solar cell according to the present disclosure;

FIG. 10 is a flow chart showing sequential steps in an exemplary process for the formation thereof;

FIG. 11 is a cross-sectional side view of a fourth embodiment of a thin film solar cell according to the present disclosure; and

FIG. 12 is a flow chart showing sequential steps in an exemplary process for the formation thereof.

All drawings are schematic and are not drawn to scale.

### DETAILED DESCRIPTION

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected,” refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the embodiments. Accordingly, the disclosure expressly should not be limited to such embodiments illustrating some possible non-limiting combination of features that can exist alone or in other combinations of features; the scope of the disclosure being defined by the claims appended hereto. The terms “chip” and “die” are used interchangeably herein.

The inventors have discovered that forming a thin film TCO seed layer between the absorber layer and thicker bulk or main TCO top electrode layer in some embodiments improves (i.e. increases) adhesion of the top electrode layer to the absorber layer. Advantageously, the TCO top electrode layer is more resistant to peeling damage with the TCO seed layer, thereby improving the performance and reliability of the solar cell particularly when the solar cell undergoes thermal cycling which induces peeling and separation of the TCO top electrode layer.

In some embodiments, the forgoing adhesion improvement and benefits are achieved by forming the TCO seed layer in a deposition process performed at lower temperatures than those typically used to form the TCO top electrode layer. This produces a seed layer with a different microstructure having a finer or smaller grain size than the main TCO top electrode layer formed subsequently thereon. The smaller grain size is associated with imparting the increased adhesion properties to the main TCO layer. Accordingly, embodiments of the present disclosure have a TCO seed layer with a different grain size than the main TCO top electrode layer.

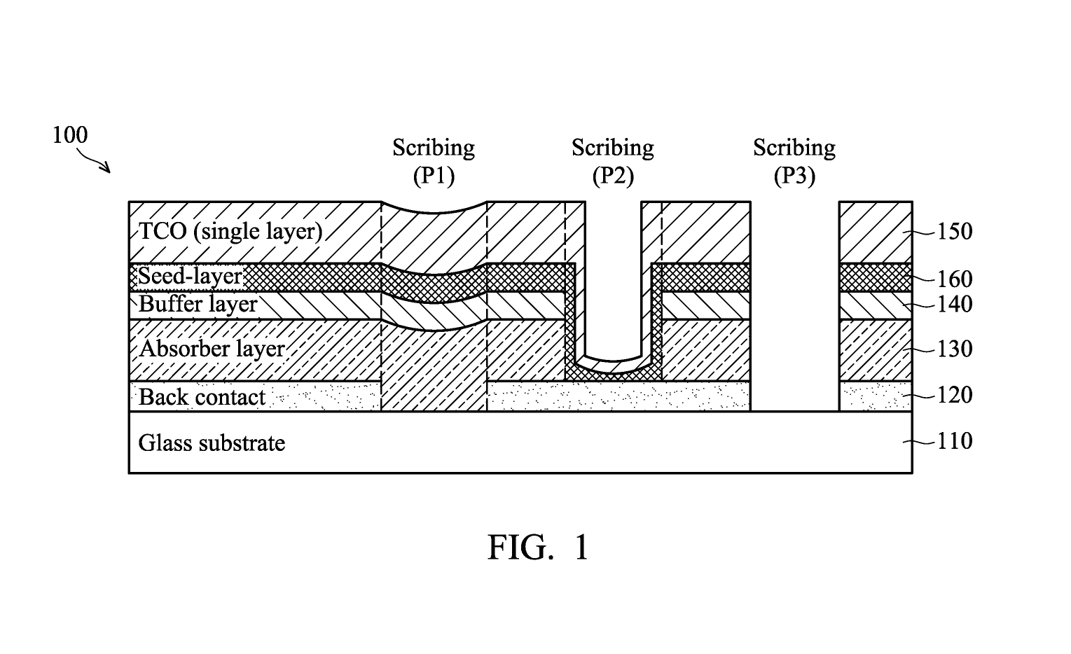

FIG. 1 shows a first embodiment of a thin film solar cell 100 having a TCO seed layer formed in-situ during the process of forming the solar cell semiconductor package. Solar cell 100 includes a substrate 110, a bottom electrode layer 120 (also referred to as a “back contact”) formed thereon, an absorber layer 130 formed thereon, a buffer layer 140 formed thereon, a TCO seed layer 160 formed thereon, and a TCO top electrode layer 150 formed thereon.

Solar cell 100 further includes micro-channels which are patterned and scribed into the semiconductor structure during the solar cell formation process to interconnect the various conductive material layers and to separate adjacent solar cells. These micro-channels or “scribe lines” as commonly referred to in the art are given “P” designations related to their function and step during the semiconductor solar cell fabrication process. The P1 and P3 scribe lines are essentially for cell isolation. P2 scribe line forms a connection. P1 scribe lines interconnect the CIGS absorber layer to the substrate and pattern the TCO panel into individual cells. P2 scribe lines remove absorber material to interconnect the top TCO electrode to the bottom electrode thereby preventing the intermediate buffer layer from acting as a barrier between the top and bottom electrodes. P3 scribe lines extend completely through the TCO, buffer layer, and absorber layer to the bottom electrode to isolate each cell defined by the P1 and P2 scribe lines.

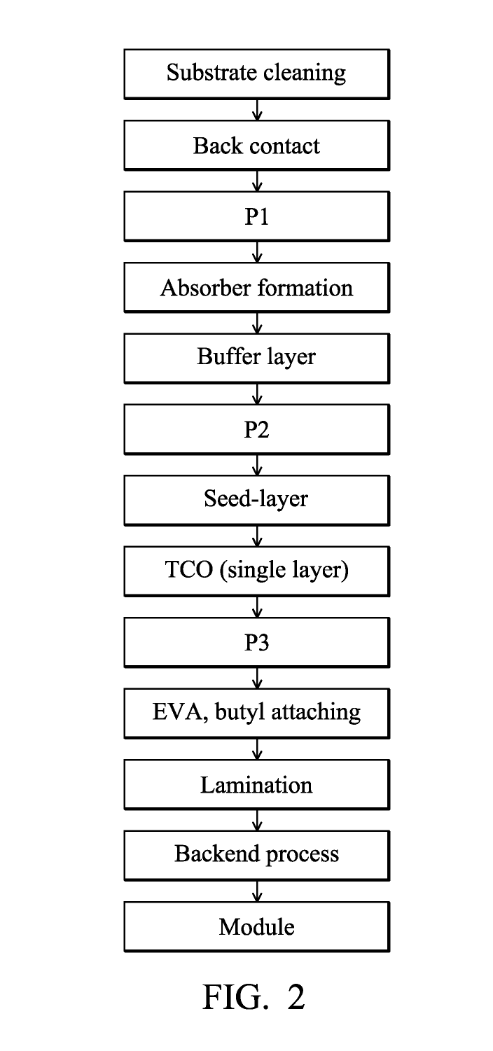

Solar cell 100 and an exemplary embodiment of a method for forming the same including TCO seed layer 160 as shown in FIG. 2 will now be described in further detail.

Referring now to FIGS. 1 and 2, substrate 110 is first cleaned in step 200 by any suitable conventional means used in the art to prepare the substrate for receiving the bottom electrode layer. In one embodiment, substrate 110 may be cleaned by using detergent or chemical in either brushing tool or ultrasonic cleaning tool.

Suitable conventional materials that may be used for substrate 110 include without limitation glass such as for example without limitation soda lime glass, ceramic, metals such as for example without limitation thin sheets of stainless steel and aluminum, or polymers such as for example without limitation polyamides, polyethylene terephthalates, polyethylene naphthalates, polymeric hydrocarbons, cellulosic polymers, polycarbonates, polyethers, and others. In one preferred embodiment, glass may be used for substrate 110.

Next, bottom electrode layer 120 is then formed on a substrate 110 (step 205) by any conventional method commonly used in the art including without limitation sputtering, atomic layer deposition (ALD), chemical vapor deposition (CVD), or other techniques.

In one embodiment, bottom electrode layer 120 may be made of molybdenum (Mo); however, other suitable electrically conductive metallic and semiconductor materials conventionally used in the art may be used such as Al, Ag, Sn, Ti, Ni, stainless steel, ZnTe, etc.

In some representative embodiments, without limitation, bottom electrode layer 120 may have a thickness ranging from about and including 0.1 to 1.5_microns (μm). In one embodiment, layer 120 has a representative thickness on the order of about 0.5 μm.

With continuing reference to FIGS. 1 and 2, P1 patterned scribe lines are next formed in bottom electrode layer 120 (step 210) to expose the top surface of substrate 110 as shown. Any suitable scribing method commonly used in the art may be used such as without limitation mechanical scribing with a stylus or laser scribing.

A p-type doped semiconductor light absorber layer 130 is next formed on top of bottom electrode layer 120 (step 215). The absorber layer 130 material further fills the P1 scribe line and contacts the exposed top surface of substrate 110 to interconnect layer 130 to the substrate, as shown in FIG. 1.

In one embodiment, absorber layer 130 may be a p-type doped chalcogenide material commonly used in the art, and such as without limitation CIGS Cu(In,Ga)Se₂ in some possible embodiments. Other suitable chalcogenide materials may be used including without limitation Cu(In,Ga)(Se, S)₂ or “CIGSS,” CuInSe₂, CuGaSe₂, CuInS₂, and Cu(In,Ga)S₂.

Suitable p-type semiconductor chalcogenide materials that may commonly be used for forming absorber layer 30 include without limitation Cu(In,Ga)Se₂, Ag(In,Ga)Se₂, Cu(In,Al)Se₂, Cu(In,Ga)(Se, S)₂, CuInSe₂, CuGaSe₂, CuInS₂, and Cu(In,Ga)S₂ or other elements of group II, III or VI of the periodic table.

Absorber layer 130 formed of CIGS may be formed by any suitable vacuum or non-vacuum process conventionally used in the art. Such processes include, without limitation, selenization, sulfurization after selenization (“SAS”), evaporation, sputtering electrodeposition, chemical vapor deposition, or ink spraying etc.

In some representative embodiments, without limitation, absorber layer 130 may have a thickness ranging from about and including 0.5 to 5.0 microns (μm). In one embodiment, absorber layer 130 has a representative thickness on the order of about 2 μm.

With continuing reference to FIGS. 1 and 2, an n-type buffer layer 140 which may be CdS is then formed on absorber layer 130 to create an electrically active n-p junction (step 220). Buffer layer 140 may be formed by any suitable method commonly used in the art. In one embodiment, buffer layer 140 may be formed by a conventional electrolyte chemical bath deposition (CBD) process commonly used in the art for forming such layers using an electrolyte solution that contains sulfur. In some representative embodiments, without limitation, buffer layer 140 may have a thickness ranging from about and including 0.005 to 0.15 microns (μm). In one embodiment, buffer layer 140 has a representative thickness on the order of about 0.015 μm.

After forming CdS buffer layer 140, the P2 scribe lines are next cut through the absorber layer 130 to expose the top surface of the bottom electrode 120 within the open scribe line or channel (step 225). Any suitable method conventionally used in the art may be used to cut the P2 scribe line as previously described, including without limitation mechanical (e.g. cutting stylus) or laser scribing. The P2 scribe line will later be filled with a conductive material from top electrode layer 150 to interconnect the top electrode to the bottom electrode layer 120.

With continuing reference to FIGS. 1 and 2, after forming the P2 scribe lines, a light transmitting n-type doped seed layer 160 and top electrode layer 150 made of a TCO material are next formed on top of buffer layer 140 for collecting current (electrons) from the cell, which ideally pass a majority of incident light on the solar cell directly through to the light absorbing layer 130 (step 230). In this first embodiment, the seed layer 160 is formed first followed by formation of the main layer 150. The top electrode carries the charge collected to an external circuit. The P2 scribe line is also at least partially filled with the TCO material from both the TCO seed layer and main TCO layer as shown in FIG. 1 covering the vertical sidewalls of the P2 scribe line and the top of bottom electrode layer 120 lying therein to form an electrical connection between the top electrode layer 150 and bottom electrode 120 creating an electron flow path. The vertical sidewalls are defined by at least the exposed sides of the absorber layer 130 and buffer layer 140. In this first embodiment shown in FIG. 1, the TCO seed layer 160 is interspersed between the bulk TCO top electrode layer 150 and sidewalls in the P2 scribe line.

Aluminum (Al) and Boron (B) are two possible n-type dopant that is commonly used for TCO top electrodes in thin film solar cells; however, others suitable conventional dopants may be used such as without limitation Aluminum (Al), Boron (B), Gallium (Ga), Indium (In) or other elements of group III of the periodic table. TCO top electrode layer 150 may be doped by any suitable method commonly used in the art, including without limitation ion implantation.

In one embodiment, the TCO used for top electrode layer 150 may be any conventional material commonly used in the art for thin film solar cells. Suitable TCOs that may be used include without limitation zinc oxide (ZnO), Boron doped ZnO (“BZO”), Aluminum doped ZnO (“AZO”), Gallium doped ZnO (“GZO”), Indium doped ZnO (“IZO”), fluorine tin oxide (“FTO” or SnO₂:F), indium tin oxide (“ITO”), a carbon nanotube layer, or any other suitable coating materials possessing the desired properties for a top electrode. In one preferred embodiment, the TCO used is BZO.

In some possible embodiments where top electrode layer 150 may be made of Boron doped ZnO or “BZO”, it should be noted that a thin intrinsic ZnO film may form on top of absorber layer 130 (not shown) during formation of the thicker n-type doped TCO top electrode layer 150.

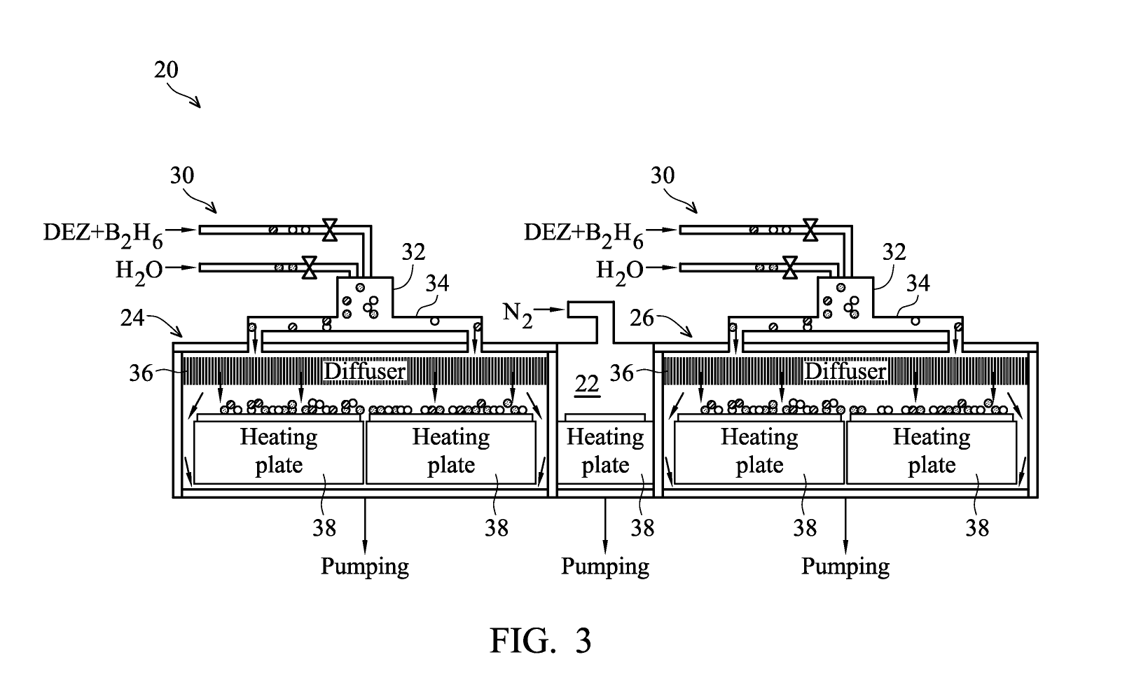

FIG. 3 shows one possible apparatus for forming TCO seed layer 160 and main TCO top electrode layer 150. In one embodiment, the apparatus is a CVD cluster tool 20 as will be known to those skilled in the art having a buffer chamber 22 and at least two process reaction chambers 24, 26 for forming the TCO seed and main top electrode layers on substrate 110. CVD tool 20 includes a process gas supply system 30 which introduces the process gases containing the chemical TCO layer precursors (e.g. without limitation DEZ for formation of ZnO TCO material), dopant in some embodiments for seed layer 160 (optional) and main bulk TCO layer 150, and other process gases into a mixing chamber 32 provided for each reaction chamber 24, 26. Gas flows from the mixing chamber 32 through a header tube 34 into a gas injection diffuser 36 located at the top of each reaction chamber 24, 26. Diffuser 36 (also known by the term “showerhead” in the art) contains a plurality of openings through which gas is uniformly distributed throughout the reaction chamber. A heating susceptor or plate 38 is disposed in each reaction chamber which is configured to support and heat substrate 110 during the film deposition process. Buffer chamber 22 includes a heating plate 38 and may include an insert gas supply (e.g. nitrogen). The buffer chamber is used only for preheating the temperature of the solar cell substrate 110 to be processed in the reaction chambers 24, 26 for increasing the temperature of the substrate from room temperature to approximately or just below the process temperature of the substrate to be used in the respective reaction chamber, thereby shortening the process time in the reaction chamber and throughput of the CVD tool.

The foregoing CVD tools are commercially-available, and their arrangement and operation are well known to those skilled in the art without further elaboration.

Referring to FIGS. 1-3, the TCO seed layer 160 is formed in one embodiment by preheating a solar cell substrate 110 in buffer chamber 22. The substrate 110 has the absorber layer 130 and CdS buffer layer 140 already formed, and the P2 scribe lines already completed as described above. The temperature of the structure is raised to the desired temperature, ideally closer to or about the substrate process temperature to be used in reaction chamber 24 in which the seed layer 160 will be formed. After preheating substrate 110, the substrate is transferred to reaction chamber 24. The substrate 110 is heated to the desired process temperature. In one embodiment, the substrate process temperature is in the range from about and including 100-140 degrees C. Ideally, it is desirable that the TCO seed layer formation temperature be less than the substrate temperature to be used for formation of the bulk main TCO top electrode layer as this will produce a smaller grain size in the seed layer than the bulk layer, which will provide the desired improved adhesion characteristics to the top electrode layer for adhesion on buffer layer 140 and absorber layer 130.

Once the desired substrate process temperature has been reached, the TCO seed layer formation process is started by introducing the process gases into reaction chamber 24. The film deposition process continues for a period of time sufficient to form the desired thickness of the seed layer. In exemplary embodiments, TCO seed layer 160 has a thickness less than the bulk main TCO top electrode layer 150. In one representative exemplary embodiment, without limitation, TCO seed layer 160 has a thickness of about and including 50-300 nm. This is sufficient for forming a seed layer that satisfactorily increases the adhesion properties the main TCO top electrode layer 150 to reduce or eliminate peeling. By contrast, TCO top electrode layer 150 in some embodiments has a thickness of about and including 1000-3000 nm for good current collection performance. Accordingly, in some embodiments, TCO seed layer 160 has a thickness that is less than half of the main TCO layer 150.

Accordingly, in some embodiments, it is desirable for the TCO seed layer 160 thickness to be less than the TCO top electrode layer 150 since the lower temperature formed seed layer tends to have a higher resistivity than the bulk top electrode layer which inhibits current flow and reduces solar cell performance. The TCO seed layer 160 therefore should have a thickness sufficient to improve adhesion of the bulk TCO layer 150 to the absorber layer 130, while not being excessively thick to the point that would degrade solar cell performance. Next, the substrate 110 with TCO seed layer 160 formed thereon is either transferred directly into bulk TCO reaction chamber 26, or alternatively transferred into buffer chamber 22 for rapid preheating of the substrate before introduction into chamber 26. In the latter case, the substrate 110 is heated close or approximately to the substrate process temperature to be used in bulk TCO reaction chamber 26. Since the bulk TCO layer 150 deposition process is performed in exemplary embodiments at a temperature higher than the TCO seed layer 160 formation, the preheat step in buffer chamber 22 may be desirable to reduce process time in bulk TCO reaction chamber 26. After preheating, the substrate is transferred to reaction chamber 26.

With continuing reference to FIGS. 1-3, the bulk main TCO top electrode layer is next formed directly onto seed layer 160 of the substrate 110 in reaction chamber 26 in a manner similar to formation of the TCO seed layer 160 already described above. However, the substrate is heated to a higher process temperature by heater plate 38. In one embodiment, the substrate process temperature used is without limitation approximately at least 190 degrees in bulk TCO reaction chamber 26. This produces a resulting main TCO top electrode layer with a larger grain size than the seed layer 160. When completed, the partially completed thin film solar cell would appear as shown in FIG. 1. In some embodiments, the high temperature bulk TCO top electrode layer 150 is formed between about and including 195-200 degrees C.

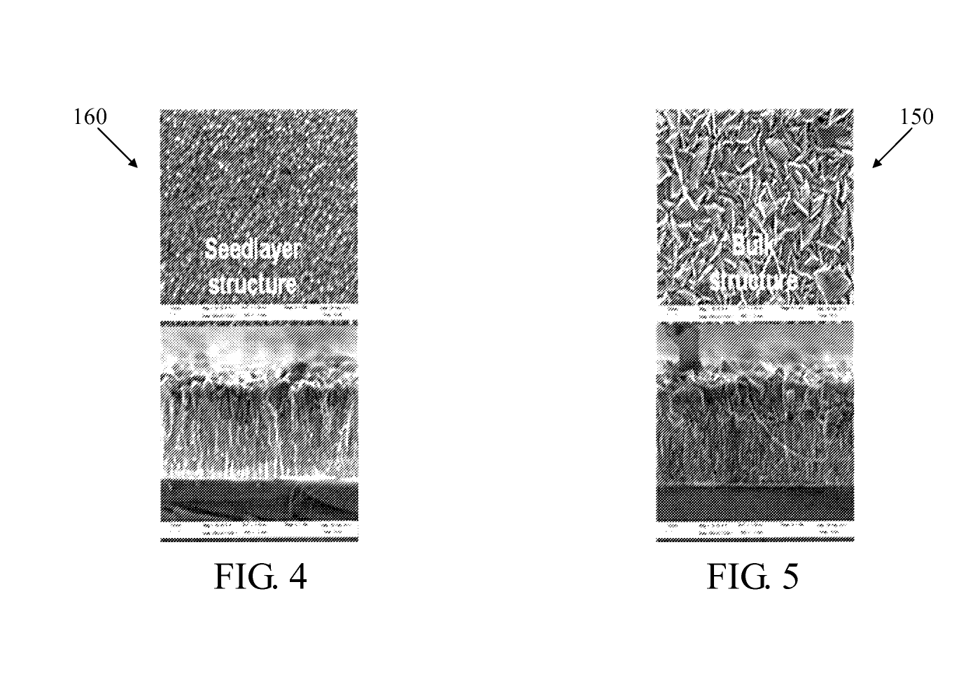

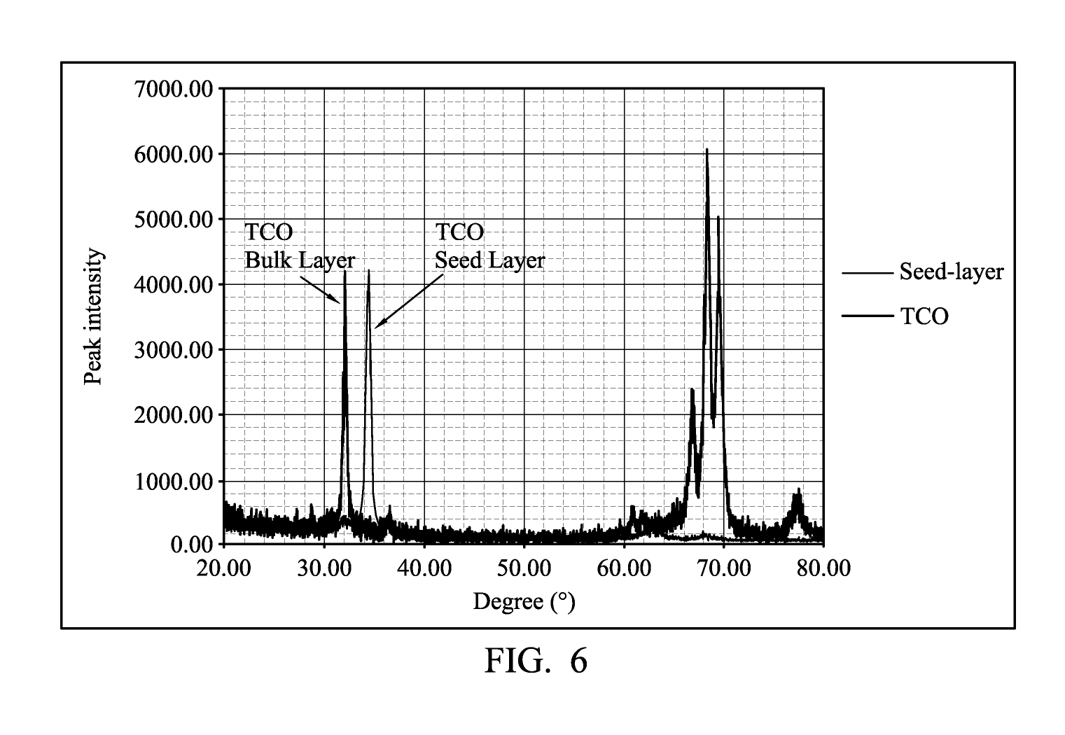

FIGS. 4 and 5 are actual scanning electron microscope (SEM) images contrasting the seed layer 160 microstructure with the higher temperature formed bulk TCO layer 150 grain structure produced according to embodiments of the present disclosure. In contrast to the TCO bulk layer formed at higher deposition temperatures, the smaller grain size of the seed layer 160 polycrystalline structure associated with improving the adhesive property of the TCO top electrode layer 150 is evident. X-ray diffraction (XRD) analysis of the TCO seed layer 160 and bulk top electrode layer 150 formed was conducted. FIG. 6 is a plot of reflected intensities versus the detector angle of the XRD analysis which shows that the TCO seed layer 160 polycrystalline structure has crystals with a different orientation angle of about 34.4 degrees in contrast to the bulk TCO layer 150 with an angle of about 32 degrees, thereby further confirming the different crystalline orientation and grain structure of the seed layer. The different structure of the TCO seed layer and adhesion properties are achieved through the lower CVD deposition temperatures used according to the present disclosure.

Although formation of the TCO seed layer 160 and top electrode layer 150 are described herein with respect to using a CVD process in one non-limiting embodiment, it will be appreciated that other suitable film formation processes used in the semiconductor art may be used including, without limitation atomic layer deposition (ALD) and physical vapor deposition (PVD) as two possible examples. Moreover, both the TCO seed layer 160 and top electrode layer 150 may be formed in a thin film deposition tool having a single process reaction chamber without a buffer chamber for preheating the substrate. Accordingly, embodiments according to the present disclosure are not limited to the semiconductor process tools described herein.

An advantage of the foregoing process according to the present disclosure is that the TCO seed layer 160 and top electrode layer 150 are both formed in the same machine, and are comprised of the same material. This creates economies in the solar cell formation fabrication process flow and reduces costs.

With continuing reference now to FIGS. 1 and 2, following formation of the TCO seed layer 160 and top electrode layer 150 described above, the P3 scribe line is formed in thin film solar cell 100 (step 240). The P3 scribe line extends through (from top to bottom) TCO top electrode layer 150, TCO seed layer 160, buffer layer 140, absorber layer 130, and the bottom electrode layer 120 down to the top of substrate 110 as shown in FIG. 1.

Additional conventional back end of line processes and lamination may be performed as shown in FIG. 2 following formation of the thin film solar cell structure disclosed herein, as will be well known and understood by those skilled in the art. This may include laminating a top cover glass onto solar cell structure to protect the top electrode layer 150 with a suitable encapsulant therebetween, such as without limitation a combination of EVA (ethylene vinyl acetate) and butyl to seal the cell (steps 245 and 250 in FIG. 2). The EVA and butyl encapsulant is conventionally used in the art and applied directly onto the top electrode layer 150 in the present embodiment, followed by applying the top cover glass thereon.

Suitable further back end processes may then be completed as shown in FIG. 2 which may include forming front conductive grid contacts and one or more anti-reflective coatings (not shown) above top electrode 150 in a conventional manner well known in the art. The grid contacts will protrude upwards through and beyond the top surface of any anti-reflective coatings for connection to external circuits. The solar cell fabrication process produces a finished and complete thin film solar cell module.

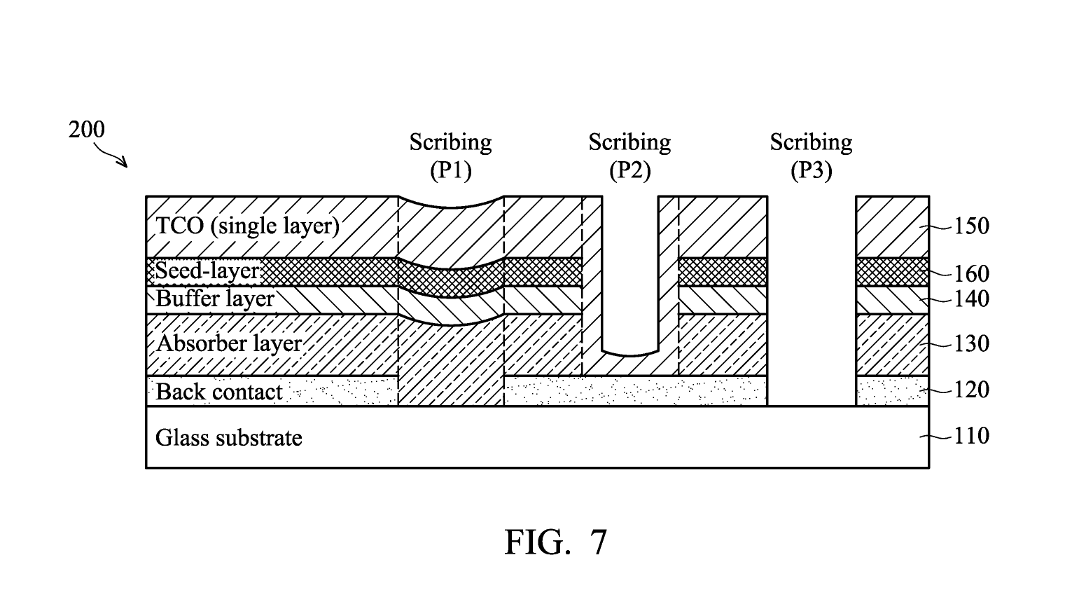

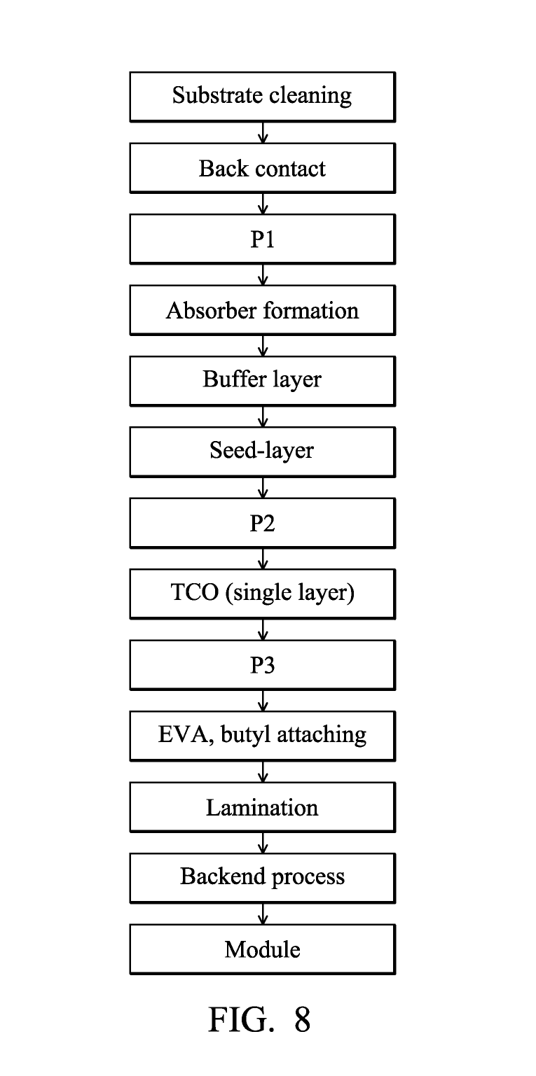

FIGS. 7 and 8 respectively show a second embodiment of a thin film solar cell 200 and method for forming the same. The second embodiment and method are similar to the first embodiment and process for fabricating thin film solar cell 100 already described (see FIGS. 1 and 2) and includes forming a TCO seed layer 160 and bulk top electrode layer 150. However, the sequence of the same formation steps for the TCO seed layer 160, top electrode layer 150, and P2 scribe line are varied as shown in FIG. 8 resulting in the slightly different structure shown in FIG. 7. TCO seed layer 160 is formed before the P2 scribing, which therefore results in only the main TCO top electrode layer 150 covering the sidewalls and bottom of the P2 scribe line (compare to FIG. 1). The P2 scribing removes the TCO seed layer from within the scribe line as shown in FIG. 7.

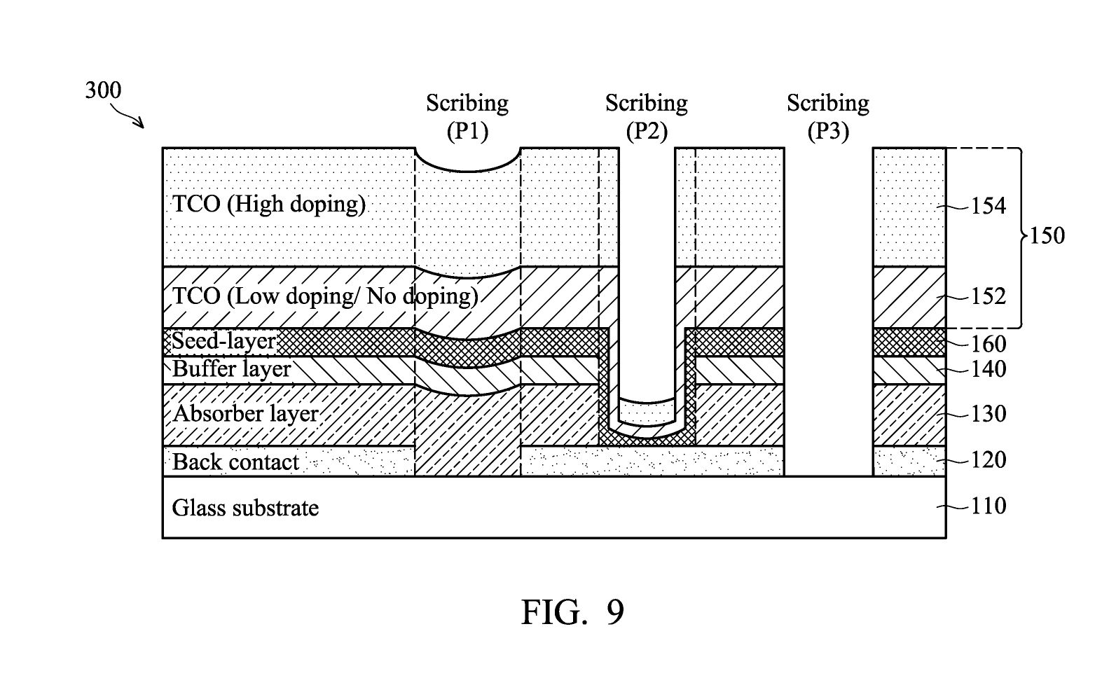

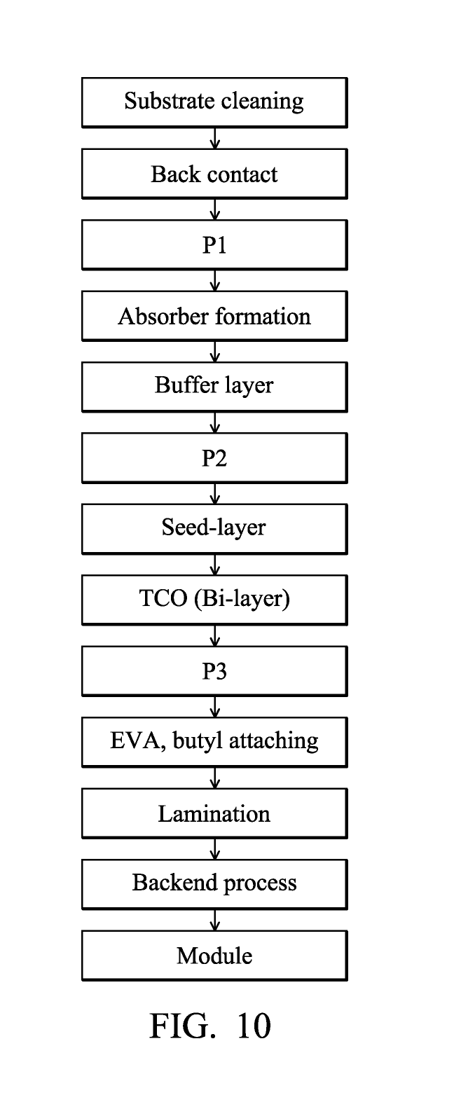

FIGS. 9 and 10 respectively show a third embodiment of a thin film solar cell 300 and method for forming the same. The third embodiment and method are similar to the first embodiment and process for fabricating thin film solar cell 100 already described (see FIGS. 1 and 2) and includes forming a TCO seed layer 160 and bulk top electrode layer 150. However, formation of the bulk TCO top electrode layer 150 is comprised of forming a two-part or bi-layer comprising a lower TCO layer 152 and an upper TCO layer 154. In one embodiment, upper TCO layer 154 is formed directly on the lower TCO layer 152 which is formed directly on TCO seed layer 160, as shown. The bi-layer construction provides the ability to form a lower TCO layer 152 with different dopant levels than the upper TCO layer 154. In some exemplary embodiments, lower TCO layer 152 has low doping or no doping at all, and upper TCO layer 154 has high doping in some embodiments. This bi-layer construction is attributed with improving current transmission and lowering resistivity in the top electrode layer thereby improving solar cell performance and efficiency in contrast to some single TCO top electrode layers.

Accordingly, the bulk lower TCO layer 152 has a low dopant level or no dopant at all (i.e. undoped) while the bulk upper TCO layer 154 has a higher dopant level with respect to the lower layer. Any suitable dopants may be used including those already previously described herein used for doping TCO in solar cells.

Accordingly, with continuing reference to FIGS. 9 and 10, the step of forming the bi-layer bulk TCO top electrode layer 150 includes first depositing the lower TCO layer 152 followed by depositing the upper TCO layer 154. In one embodiment, both lower and upper TCO layers 152, 154 are formed at higher temperatures (e.g. 190 degrees C. or above) similarly to the single TCO top electrode layer 150 in FIGS. 1 and 2 than lower temperatures used to form the smaller grained TCO seed layer 160. In some embodiments, the upper TCO layer 154 may be formed sequentially in the same reaction chamber 26 as the lower layer 152 by changing the concentration of dopants introduced into the reaction chamber with the chemical precursor gas flow over time. In one embodiment, the lower and upper TCO layers 152, 154 are formed of the same TCO material. In other possible embodiments contemplated, it is possible to form the lower and upper TCO layers 152, 154 out of different TCO materials.

In one exemplary embodiment, without limitation, the upper TCO layer 154 may have a representative thickness of about and including 500-1500 nm and the lower TCO layer 152 may have a representative thickness of about and including 1000-3000 nm. Accordingly, in some embodiments the lower and upper TCO layers 152, 154 may have the approximately the same or different thicknesses.

The lower TCO layer 152 and upper TCO layer 154 of the top electrode bi-layer structure in some embodiments have similar grain size microstructures as the single layer TCO top electrode layers shown in FIGS. 1 and 7, and described herein.

In the embodiment shown in FIG. 9, TCO seed layer 160 is formed after the P2 scribing, which therefore results in only both the bi-layer TCO top electrode layer 150 (comprised of lower and upper TCO layers 152, 154) and seed layer 160 covering the sidewalls and bottom of the P2 scribe line.

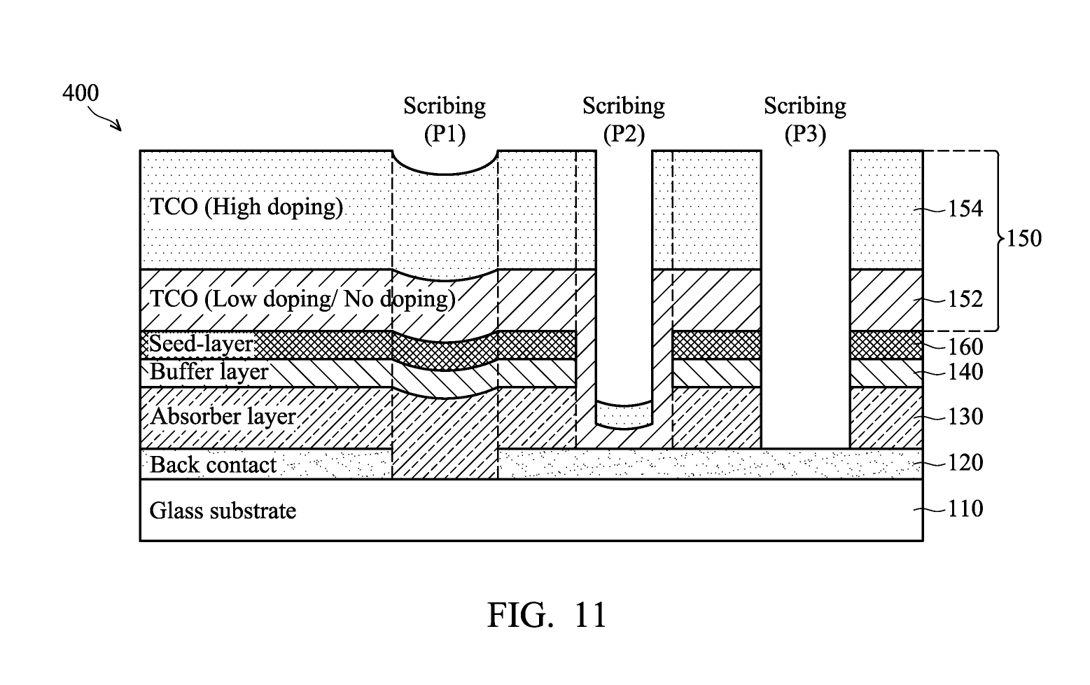

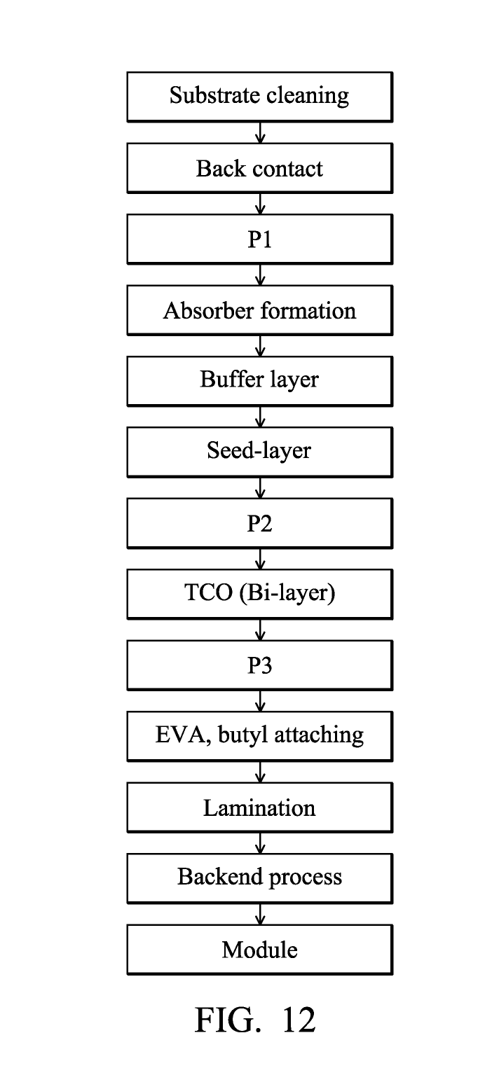

FIGS. 11 and 12 respectively show a fourth embodiment of a thin film solar cell 400 and method for forming the same. The fourth embodiment and method are similar to the third embodiment and process for fabricating thin film solar cell 300 already described (see FIGS. 9 and 10) with respect to forming a TCO seed layer 160 and high temperature formed bulk top electrode layer 150 comprised of a bi-layer construction including lower TCO layer 152 and upper TCO layer 154. However, TCO seed layer 160 in solar cell 400 is formed before the P2 scribing, which therefore results in only the main bi-layer TCO top electrode layer 150 covering the sidewalls and bottom of the P2 scribe line (compare FIG. 11 to FIG. 9). The P2 scribing removes the TCO seed layer 160 from within the scribe line as shown in FIG. 11 (also similarly to FIGS. 7 and 8 having a single layer TCO top electrode layer 150). Since the P2 scribe removes sidewalls of seed layer 160, the current travels through the bulk TCO in the sidewall instead of the seed layer thereby improving current flow and solar cell performance/efficiency.

According to one exemplary embodiment, a thin film solar cell includes a bottom electrode layer formed on a substrate, a semiconductor absorber layer formed on the bottom electrode layer, a buffer layer formed on the absorber layer, a transparent conductive oxide (TCO) seed layer formed on the buffer layer; and a bulk TCO top electrode layer formed on the TCO seed layer. The bulk TCO top electrode layer is electrically connected to the bottom electrode layer through a P2 scribe line defining a vertical channel extending through the buffer and absorber layers. The TCO seed layer has a different microstructure than the bulk TCO top electrode layer, thereby improving adhesion of the top electrode layer to the absorber-buffer layers. In one embodiment, the TCO seed layer has a microstructure having a smaller grain size than the bulk TCO top electrode layer.

According to another exemplary embodiment, a thin film solar cell with bi-layer top electrode layer includes a bottom electrode layer formed on a substrate, a semiconductor absorber layer formed on the bottom electrode layer, a buffer layer formed on the absorber layer, a transparent conductive oxide (TCO) seed layer formed on the buffer layer, and a bulk bi-layer TCO top electrode layer formed on the TCO seed layer. The bulk bi-layer TCO top electrode layer is electrically connected to the bottom electrode layer through a P2 scribe line defining a vertical channel extending through the buffer and absorber layers. The bulk bi-layer TCO top electrode layer comprises a lower TCO layer and an upper TCO layer formed on the lower TCO layer, the upper TCO layer having a different dopant concentration than a dopant concentration of the lower TCO layer. In one embodiment, the upper TCO layer has a higher dopant level than the lower TCO layer which has a low dopant level or is undoped. The TCO seed layer has a different microstructure than the bulk bi-layer TCO first or second top electrode layers. In one embodiment, the TCO seed layer has a microstructure having a smaller grain size than the lower TCO layer or the upper TCO layer.

According to one exemplary embodiment, a method for forming a thin film solar cell includes the steps of: depositing a conductive bottom electrode layer on a substrate; depositing an absorber layer on the bottom electrode layer; depositing a buffer layer on the absorber layer; depositing a TCO seed layer on the buffer layer at a first temperature; and depositing a bulk TCO top electrode layer on the TCO seed layer at a second temperature higher than the first temperature.

While the foregoing description and drawings represent exemplary embodiments of the present disclosure, it will be understood that various additions, modifications and substitutions can be made therein without departing from the spirit and scope and range of equivalents of the accompanying claims. In particular, it will be clear to those skilled in the art that the present disclosure can be embodied in other forms, structures, arrangements, proportions, sizes, and with other elements, materials, and components, without departing from the spirit or essential characteristics thereof. In addition, numerous variations in the methods/processes and/or control logic as applicable described herein can be made without departing from the spirit of the disclosure. One skilled in the art will further appreciate that the disclosure can be used with many modifications of structure, arrangement, proportions, sizes, materials, and components and otherwise, used in the practice of the disclosure, which are particularly adapted to specific environments and operative requirements without departing from the principles of the present disclosure. The presently disclosed embodiments are therefore to be considered in all respects as illustrative and not restrictive, the scope of the disclosure being defined by the appended claims and equivalents thereof, and not limited to the foregoing description or embodiments. Rather, the appended claims should be construed broadly, to include other variants and embodiments of the disclosure, which can be made by those skilled in the art without departing from the scope and range of equivalents of the disclosure.

1. A thin film solar cell comprising:
a bottom electrode layer formed on a substrate;
a semiconductor absorber layer formed on the bottom electrode layer;
a buffer layer formed on the absorber layer;
a transparent conductive oxide (TCO) seed layer formed on the buffer layer; and
a bulk TCO top electrode layer formed on the TCO seed layer, the bulk TCO top electrode layer being electrically connected to the bottom electrode layer of an adjacent solar cell through a P2 scribe line defining a vertical channel extending through the buffer and absorber layers;
wherein the TCO seed layer has a different microstructure than the bulk TCO top electrode layer.

2. The solar cell of claim 1, wherein the TCO seed layer has a microstructure having a smaller grain size than the bulk TCO top electrode layer.

3. The solar cell of claim 1, wherein the TCO seed layer has a film thickness less than the thickness of the bulk TCO top electrode layer.

4. The solar cell of claim 3, wherein the TCO seed layer has a film thickness of between about 50 nm and about 300 nm.

5. The solar cell of claim 4, wherein the bulk TCO top electrode layer has a film thickness of 1000 nm or greater.

6. The solar cell of claim 1, wherein the TCO seed layer has a polycrystalline structure of crystals with a different orientation angle than crystals in the bulk TCO top electrode layer.

7. The solar cell of claim 1, wherein the TCO seed layer extends into the P2 scribe line.

8. The solar cell of claim 7, wherein the TCO seed layer is interspersed between the bulk TCO top electrode layer and sidewalls within the P2 scribe line defined by the absorber layer and buffer layer.

9. The solar cell of claim 1, wherein the absorber layer comprises p-type chalcogenide materials or CdTe.

10. The solar cell of claim 1, wherein the absorber layer comprises a material selected from the group consisting of Cu(In,Ga)Se₂, Cu(In,Ga)(Se, S)₂, CuInSe₂, CuGaSe₂, CuInS₂, and Cu(In,Ga)S₂.

11. The solar cell of claim 1, wherein the top electrode is an n-type material selected from the group consisting of zinc oxide, aluminum doped zinc oxide, gallium doped zinc oxide, indium doped zinc oxide, fluorine tin oxide, indium tin oxide, indium zinc oxide, antimony tin oxide (ATO), and a carbon nanotube layer.

12. A thin film solar cell comprising:
a bottom electrode layer formed on a substrate;
a semiconductor absorber layer formed on the bottom electrode layer;
a buffer layer formed on the absorber layer;
a TCO seed layer formed on the buffer layer;
a bulk bi-layer TCO top electrode layer formed on the TCO seed layer, the bulk bi-layer TCO top electrode layer being electrically connected to the bottom electrode layer of an adjacent solar cell through a P2 scribe line defining a vertical channel extending through the buffer and absorber layers;
wherein the bulk bi-layer TCO top electrode layer comprises a lower TCO layer and an upper TCO layer formed on the lower TCO layer, the upper TCO layer having a different dopant concentration than a dopant concentration of the lower TCO layer;
wherein the TCO seed layer has a different microstructure than the lower TCO layer or the upper TCO layer of the bulk bi-layer TCO top electrode layer.

13. The solar cell of claim 12, wherein the TCO seed layer has a microstructure having a smaller grain size than the lower TCO layer or the upper TCO layer.

14. The solar cell of claim 12, wherein the TCO seed layer has a film thickness less than the thickness of the lower TCO layer or the upper TCO layer.

15. The solar cell of claim 14, wherein the dopant concentration of the upper TCO layer is higher than the dopant concentration of the lower TCO layer.

16. The solar cell of claim 12, wherein the TCO seed layer has a polycrystalline structure of crystals with a different orientation angle than crystals in the bulk TCO top electrode layer.

17. The solar cell of claim 12, wherein the TCO seed layer extends into the P2 scribe line.

18-20. (canceled)

21. A thin film solar cell comprising:
a bottom electrode layer formed on a substrate;
a semiconductor absorber layer formed on the bottom electrode layer;
a buffer layer formed on the absorber layer;
a transparent conductive oxide (TCO) seed layer formed on the buffer layer; and
a bulk TCO top electrode layer formed on the TCO seed layer, the bulk TCO top electrode layer being electrically connected to the bottom electrode layer of an adjacent solar cell through a P2 scribe line defining a vertical channel extending through the buffer and absorber layers;
wherein the TCO seed layer has a different microstructure than the bulk TCO top electrode layer; and the bulk TCO top electrode layer extends into the P2 scribe line.

22. The solar cell of claim 21, wherein the TCO seed layer has a microstructure having a smaller grain size than the bulk TCO top electrode layer.

23. The solar cell of claim 21, wherein the TCO seed layer extends into the P2 scribe line.
